(19) United States
(12) Patent Application Publication
(10) Pub. No.: US 2016/0268154 A1
(43) Pub. Date: Sep. 15, 2016

(54) INSULATING SUBSTRATE AND SEMICONDUCTOR DEVICE

(71) Applicant: MITSUBISHI ELECTRIC CORPORATION, Tokyo (JP)

(72) Inventors: Akinori HIRAOKA, Tokyo (JP); Kazuhiro KURIAKI, Tokyo (JP)

(73) Assignee: Mitsubishi Electric Corporation, Tokyo (JP)

(21) Appl. No.: 15/035,926

(22) PCT Filed: Mar. 7, 2014
(86) PCT No.: PCT/JP2014/056027

§ 371 Date: May 11, 2016

(51) Int. Cl. H01L 21/683; H01L 23/367; H01L 23/373; H01L 23/15; H01L 21/56; H01L 23/495

(52) U.S. Cl. CPC H01L 21/6835; H01L 21/568; H01L 23/49575; H01L 23/49568; H01L 23/49551; H01L 23/3735; H01L 23/15; H01L 23/3672; H01L 2221/68386; H01L 2221/68318; H01L 2224/48137; H01L 2224/48247

(57) ABSTRACT

A thermosetting double-sided adhesive insulating resin is disposed on a ceramic plate. A metal plate is disposed on the thermosetting double-sided adhesive insulating resin and bonded to an upper surface of the ceramic plate via the thermosetting double-sided adhesive insulating resin. The thermosetting double-sided adhesive insulating resin is low cost and free from problems with an aspect of member supply as well. Since the thermosetting double-sided adhesive insulating resin eliminates a divergence in coefficients of linear expansion between the ceramic plate and the metal plate, it is possible to prevent cracking of the ceramic plate during heating and peeling of the metal plate from the ceramic plate. Since the thermosetting double-sided adhesive insulating resin can maintain adhesiveness, it is possible to prevent the generation of voids, thereby improving product reliability. Since the thermosetting double-sided adhesive insulating resin hardens during thermoforming, it is possible to perform molding processing.

### FIELD

The present invention relates to an insulating substrate using a ceramic plate, and a semiconductor device.

### BACKGROUND

Power devices are required to improve heat dissipation. A high heat dissipation filler is therefore included in an insulating sheet to improve heat dissipation performance, which, however, involves a high material cost and also has a problem in an aspect of member supply. Therefore, ceramics having high thermal conductivity is used instead of the insulating sheet.

Conventionally, a metal plate and a ceramic plate having different coefficients of linear expansion are bonded together through thermo-compression or using a brazing material whose principal ingredient is silver. However, in the case of thermo-compression, there is concern that voids may be generated due to insufficient adhesiveness during heating in a reliability test. In the case of bonding using a brazing material, since a contractive force of a metal plate exceeds that of a ceramic plate during cooling, the ceramic plate may be broken or the metal plate may be peeled off from the ceramic plate. Moreover, conventional bonding methods involve a problem that the member cost is high. In contrast, a technique of providing thermoplastic polyimide between the ceramic plate and the metal plate is disclosed (e.g., see PTL 1).

### CITATION LIST

### Patent Literature

[PTL 1] JP2011-104815 A

### SUMMARY

### Technical Problem

However, thermoplastic resin such as thermoplastic polyimide changes to a liquid state during heating and molding, causing a problem that molding processing is not possible.

The present invention has been implemented to solve the above-described problem, and it is an object of the present invention to provide an insulating substrate and a semiconductor device which are low cost, free from problems with an aspect of member supply, capable of improving product reliability and enabling molding processing.

### Solution to Problem

An insulating substrate device according to the present invention includes: a ceramic plate; a first thermosetting double-sided adhesive insulating resin on the ceramic plate; and a first metal plate on the first thermosetting double-sided adhesive insulating resin and bonded to an upper surface of the ceramic plate via the first thermosetting double-sided adhesive insulating resin.

### Advantageous Effects of Invention

In the present invention, the ceramic plate and the first metal plate are bonded together via the first thermosetting double-sided adhesive insulating resin. The first thermosetting double-sided adhesive insulating resin is low cost and free from problems with an aspect of member supply as well. Since the first thermosetting double-sided adhesive insulating resin eliminates a divergence in coefficients of linear expansion between the ceramic plate and the first metal plate, it is possible to prevent cracking of the ceramic plate during heating and peeling of the first metal plate from the ceramic plate. Furthermore, since the first thermosetting double-sided adhesive insulating resin can maintain adhesiveness, it is possible to prevent the generation of voids. As a result, product reliability can be improved. Furthermore, since the first thermosetting double-sided adhesive insulating resin hardens during thermoforming, it is possible to perform molding processing.

### BRIEF DESCRIPTION OF THE DRAWINGS

FIG. 1 is a perspective view of a semiconductor device according to Embodiment 1 of the present invention, part of which is cut out.

FIG. 2 is a cross-sectional view illustrating the insulating substrate according to Embodiment 1 of the present invention.

FIG. 3 is a cross-sectional view illustrating an insulating substrate according to Embodiment 2 of the present invention.

FIG. 4 is a cross-sectional view illustrating a semiconductor device according to Embodiment 3 of the present invention.

FIG. 5 is a cross-sectional view illustrating a semiconductor device according to Embodiment 4 of the present invention.

FIG. 6 is a cross-sectional view illustrating a semiconductor device according to Embodiment 5 of the present invention.

### DESCRIPTION OF EMBODIMENTS

An insulating substrate and a semiconductor device according to the embodiments of the present invention will be described with reference to the drawings. The same components will be denoted by the same symbols, and the repeated description thereof may be omitted.

### Embodiment 1

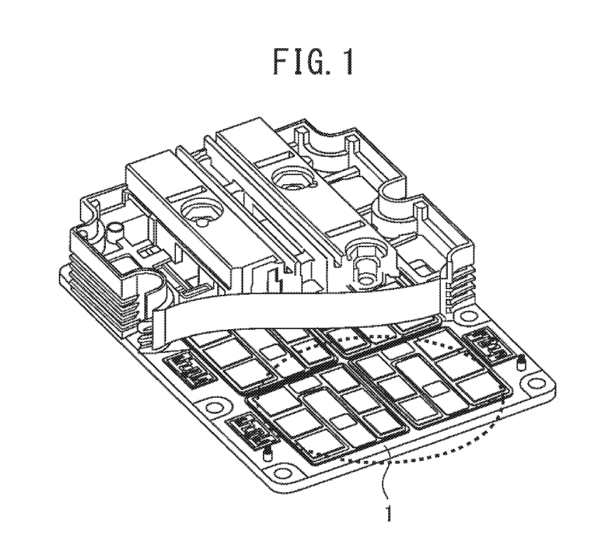

FIG. 1 is a perspective view of a semiconductor device according to Embodiment 1 of the present invention, part of which is cut out. An insulating substrate 1 is provided in a portion enclosed by a broken line in FIG. 1.

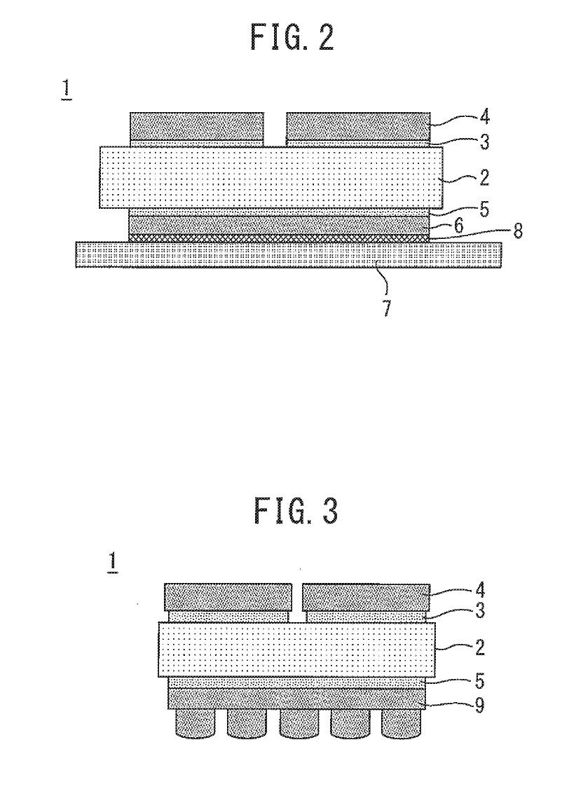

FIG. 2 is a cross-sectional view illustrating the insulating substrate according to Embodiment 1 of the present invention. The insulating substrate 1 is an insulating substrate of a case type module. A thermosetting double-sided adhesive insulating resin 3 is disposed on a ceramic plate 2 and a metal plate 4 is disposed on the thermosetting double-sided adhesive insulating resin 3. The metal plate 4 is bonded to an upper surface of the ceramic plate 2 via the thermosetting double-sided adhesive insulating resin 3.

A thermosetting double-sided adhesive insulating resin 5 is disposed below the ceramic plate 2 and a metal plate 6 is disposed below the thermosetting double-sided adhesive insulating resin 5. The metal plate 6 is bonded to an under surface of the ceramic plate 2 via the thermosetting double-sided adhesive insulating resin 5. A base plate 7 is bonded to an under surface of the metal plate 6 via a solder 8.

The thermosetting double-sided adhesive insulating resins 3 and 5 have adhesive upper and under surfaces, which have a property of hardening when heated. More specifically, a die attach film for a common NAND flash memory is used as the thermosetting double-sided adhesive insulating resins 3 and 5. The die attach film has a structure in which a base material, an adhesive member, a conductive die attach film and a release liner, for example, are laminated in that order.

In the present embodiment, the ceramic plate 2 and the metal plate 4 are bonded together via the thermosetting double-sided adhesive insulating resin 3. The thermosetting double-sided adhesive insulating resin 3 is low cost and free from problems with an aspect of member supply as well. Since the thermosetting double-sided adhesive insulating resin 3 eliminates a divergence in coefficients of linear expansion between the ceramic plate 2 and the metal plate 4, it is possible to prevent cracking of the ceramic plate 2 during heating and peeling of the metal plate 4 from the ceramic plate 2. Furthermore, since the thermosetting double-sided adhesive insulating resin 3 can maintain adhesiveness, it is possible to prevent the generation of voids. As a result, product reliability can be improved. Furthermore, since the thermosetting double-sided adhesive insulating resin 3 hardens during thermoforming, it is possible to perform molding processing.

Furthermore, the ceramic plate 2 and the metal plate 6 are bonded together via the thermosetting double-sided adhesive insulating resin 5, and an effect similar to that described above can be obtained in this part, too.

### Embodiment 2

FIG. 3 is a cross-sectional view illustrating an insulating substrate according to Embodiment 2 of the present invention. A cooling fin 9 is used instead of the metal plate 6, the base plate 7 and the solder 8 of Embodiment 1. This cooling fin 9 is disposed below the thermosetting double-sided adhesive insulating resin 5 and bonded to an under surface of the ceramic plate 2 via the thermosetting double-sided adhesive insulating resin 5. Replacing the base plate 7 of Embodiment 1 by the cooling fin 9 can further improve heat dissipation.

### Embodiment 3

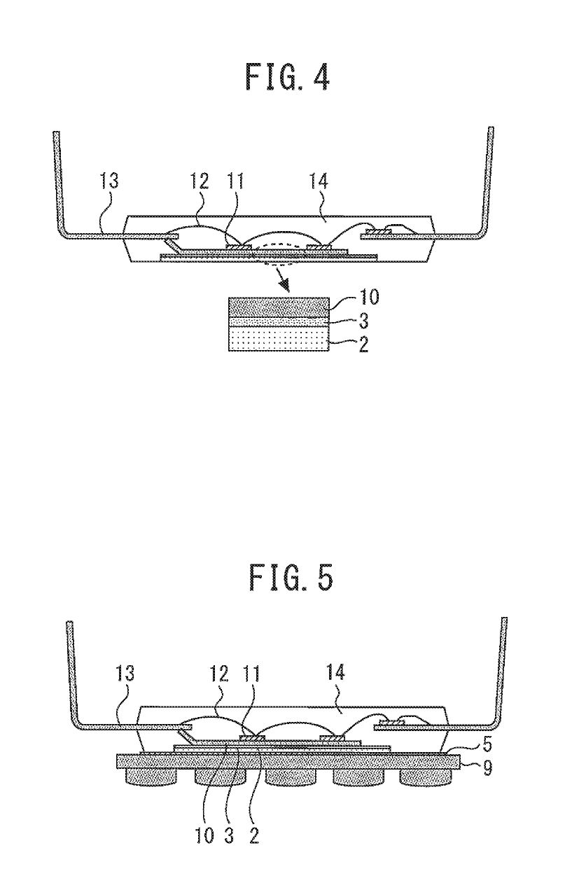

FIG. 4 is a cross-sectional view illustrating a semiconductor device according to Embodiment 3 of the present invention. This semiconductor device is a transfer mold IPM (intelligent power module). The thermosetting double-sided adhesive insulating resin 3 is disposed on the ceramic plate 2 and a lead frame 10 is disposed on the thermosetting double-sided adhesive insulating resin 3. The lead frame 10 is bonded to an upper surface of the ceramic plate 2 via the thermosetting double-sided adhesive insulating resin 3. A semiconductor element 11 is mounted on the lead frame 10. The semiconductor element 11 is connected to a lead terminal 13 via a wire 12. A resin 14 seals the semiconductor element 11 and the wire 12 or the like.

Replacing a copper-foiled insulating sheet of the transfer mold IPM by the ceramic plate 2 can improve heat dissipation and reduce the cost. In addition, effects similar to those of Embodiment 1 can be achieved.

### Embodiment 4

FIG. 5 is a cross-sectional view illustrating a semiconductor device according to Embodiment 4 of the present invention. In addition to the configuration of Embodiment 3, the thermosetting double-sided adhesive insulating resin 5 is disposed below the ceramic plate 2 and the cooling fin 9 is disposed below the thermosetting double-sided adhesive insulating resin 5. The cooling fin 9 is bonded to an under surface of the ceramic plate 2 via the thermosetting double-sided adhesive insulating resin 5. Since the present embodiment provides the ceramic plate 2 between the module and the cooling fin 9, it is possible to improve connectivity, heat dissipation and insulating properties compared to prior arts that provide a silicone grease between the two.

### Embodiment 5

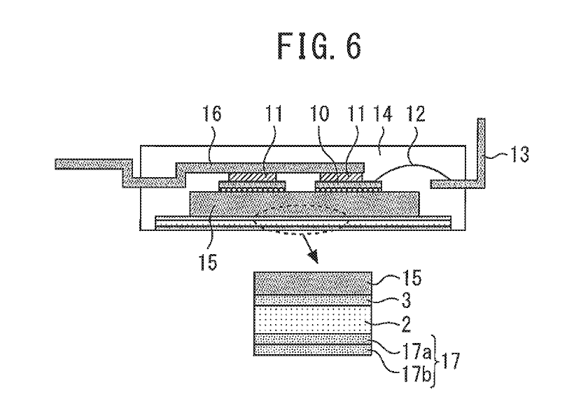

FIG. 6 is a cross-sectional view illustrating a semiconductor device according to Embodiment 5 of the present invention. This semiconductor device is a transfer mold IPM with a built-in heat spreader. The lead frame 10 is disposed on a metallic heat spreader 15 and the semiconductor element 11 is mounted on the lead frame 10. The lead frame 10 and the lead terminal 13 are connected together via the wire 12. A lead terminal 16 is connected to the semiconductor element 11. A resin 14 seals the semiconductor element 11 and the wire or the like.

The thermosetting double-sided adhesive insulating resin 3 is disposed below the heat spreader 15 and the ceramic plate 2 is disposed below the thermosetting double-sided adhesive insulating resin 3. The ceramic plate 2 is bonded to an under surface of the heat spreader 15 via the thermosetting double-sided adhesive insulating resin 3.

Thus, the transfer mold IPM with a built-in heat spreader can also achieve effects similar to those of Embodiment 3. A ceramic cracking prevention tape 17 is pasted to the under surface of the ceramic plate 2. It is thereby possible to reduce stress and prevent the ceramic plate 2 from cracking. The ceramic cracking prevention tape 17 has a structure in which a silicone-based adhesive member 17a and a polyimide film 17b, for example, are laminated together.

Note that the semiconductor element 11 is not limited to one formed of silicon but may also be formed of a wide-band gap semiconductor which has a wider band gap than that of silicon. The wide-band gap semiconductor is made of silicon carbide, nitride gallium-based material or diamond. A power semiconductor element formed of such a wide-band gap semiconductor has high withstand voltage or high maximum allowable current density, and can therefore be downsized. Using such a downsized element can reduce the size of a semiconductor device into which this element is assembled. Furthermore, since the element has high heat resistance, the cooling fin 9 can be downsized and the water cooling system can be replaced by an air cooling system, which allows the semiconductor device to be further downsized. Moreover, since the element achieves low power loss and high efficiency, it is possible to make the semiconductor device more efficient.

### REFERENCE SIGNS LIST

1 insulating substrate, 2 ceramic plate, 3 thermosetting double-sided adhesive insulating resin (first thermosetting double-sided adhesive insulating resin), 4 metal plate (first metal plate), 5 thermosetting double-sided adhesive insulating resin (second thermosetting double-sided adhesive insulating resin), 6 metal plate (second metal plate), 7 base plate, 8 solder, 9 cooling fin, 10 lead frame, 11 semiconductor element, 14 resin, 17 ceramic cracking prevention tape

1. An insulating substrate comprising:
a ceramic plate;
a first thermosetting double-sided adhesive insulating resin on the ceramic plate; and
a first metal plate on the first thermosetting double-sided adhesive insulating resin and bonded to an upper surface of the ceramic plate via the first thermosetting double-sided adhesive insulating resin.

2. The insulating substrate of claim 1, further comprising:
a second thermosetting double-sided adhesive insulating resin below the ceramic plate; and
a second metal plate below the second thermosetting double-sided adhesive insulating resin and bonded to an under surface of the ceramic plate via the second thermosetting double-sided adhesive insulating resin.

3. The insulating substrate of claim 2, further comprising a base plate bonded to an under surface of the second metal plate via a solder.

4. The insulating substrate of claim 1, further comprising:
a second thermosetting double-sided adhesive insulating resin below the ceramic plate; and
a cooling fin below the second thermosetting double-sided adhesive insulating resin and bonded to an under surface of the ceramic plate via the second thermosetting double-sided adhesive insulating resin.

5. A semiconductor device comprising:
a ceramic plate;
a first thermosetting double-sided adhesive insulating resin on the ceramic plate;
a lead frame on the first thermosetting double-sided adhesive insulating resin and bonded to an upper surface of the ceramic plate via the first thermosetting double-sided adhesive insulating resin;
a semiconductor element on the lead frame; and
a resin sealing the semiconductor element.

6. The semiconductor device of claim 5, further comprising:
a second thermosetting double-sided adhesive insulating resin below the ceramic plate; and
a cooling fin below the second thermosetting double-sided adhesive insulating resin and bonded to an under surface of the ceramic plate via the second thermosetting double-sided adhesive insulating resin.

7. The semiconductor device of claim 5, further comprising a ceramic cracking prevention tape pasted to an under surface of the ceramic plate.

8. The semiconductor device of claim 5, wherein the semiconductor element is formed of a wide-band gap semiconductor.
